(19) United States
(12) Patent Application Publication
(10) Pub. No.: US 2025/0301867 A1
(43) Pub. Date: Sep. 25, 2025

(54) DISPLAY APPARATUS

(71) Applicant: Samsung Display Co., Ltd., Yongin-Si (KR)

(72) Inventor: Ikhyoun Sung, Yongin-si (KR)

(21) Appl. No.: 18/909,947

(22) Filed: Oct. 9, 2024

(30) Foreign Application Priority Data
Mar. 22, 2024 (KR) 10-2024-0039979

(51) Int. Cl. H10K 59/131; H10K 59/124; H10K 102/00

(52) U.S. Cl. CPC H10K 59/131; H10K 59/124; H10K 2102/311

(57) ABSTRACT

A display apparatus includes a substrate including an upper surface and a lower surface, a pixel circuit layer on the upper surface of the substrate, an emission layer on the pixel circuit layer, and a bending portion including a wiring layer, a first urethane resin layer, and a second urethane resin layer, the wiring layer being electrically connected to the pixel circuit layer, the first urethane resin layer covering one surface of the wiring layer, and the second urethane resin layer covering another surface of the wiring layer.

### CROSS-REFERENCE TO RELATED APPLICATION

This application is based on and claims priority under 35 U.S.C. § 119 to Korean Patent Application No. 10-2024-0039979, filed on Mar. 22, 2024, in the Korean Intellectual Property Office, the disclosure of which is incorporated by reference herein in its entirety.

### BACKGROUND

### Field

One or more embodiments relate to a display apparatus, and more particularly, to a display apparatus having a slim bezel.

### Description of Related Art

Display apparatuses receive information about images and display the images. Display apparatuses may be used as displays for small products, such as mobile phones, or for large products, such as televisions.

A display apparatus may include pixels that receive electrical signals and emit light to display an image. Each pixel may include a light-emitting element, and for example, in the case of organic light-emitting display apparatuses, the light emitting element may be an organic light-emitting diode (OLED). In general, an organic light-emitting display apparatus includes thin-film transistors and OLEDs on a substrate, and each OLED emits light.

### SUMMARY

One or more embodiments in accordance with the present disclosure include a display apparatus having a slim bezel. However, the embodiments disclosed herein are examples and are not intended to limit the scope of the claims.

Additional aspects will be set forth in part in the description which follows and, in part, will be apparent from the description, or may be learned by practice of the presented embodiments of the disclosure.

According to one or more embodiments, a display apparatus includes a substrate including an upper surface and a lower surface, a pixel circuit layer on the upper surface of the substrate, an organic emission layer on the pixel circuit layer, and a bending portion including a wiring layer, a first urethane resin layer, and a second urethane resin layer, the wiring layer being electrically connected to the pixel circuit layer, the first urethane resin layer covering one surface of the wiring layer, and the second urethane resin layer covering another surface of the wiring layer.

According to an embodiment, one end of the bending portion may be in a groove formed on one edge of the substrate.

According to an embodiment, the first urethane resin layer may include at least one through hole, and the wiring layer and the pixel circuit layer may be electrically connected to each other through the at least one through hole of the first urethane resin layer.

According to an embodiment, the first urethane resin layer may be in direct contact with the pixel circuit layer.

According to an embodiment, the substrate may include a display area and a peripheral area, the peripheral area being around the display area.

According to an embodiment, the at least one through hole of the first urethane resin layer may be in the peripheral area.

According to an embodiment, in the peripheral area, the pixel circuit layer may include a conductive layer on the first urethane resin layer, and a gate layer on the conductive layer, the gate layer being electrically connected to the conductive layer in the peripheral area.

According to an embodiment, the wiring layer may be in direct contact with the conductive layer.

According to an embodiment, the display apparatus may further include a semiconductor layer simultaneously in contact with a lower surface of the gate layer and the conductive layer.

According to an embodiment, one end of the bending portion may be in a groove formed on one edge of the substrate.

According to an embodiment, the display apparatus may further include a lower structure layer below the substrate.

According to an embodiment, another end of the bending portion may be attached to a lower surface of the lower structure layer.

According to an embodiment, the display apparatus may further include a driving chip arranged around the other end of the bending portion on the first urethane resin layer.

According to an embodiment, the display apparatus may further include a resin member configured to seal a gap between the bending portion and the lower structure layer.

According to an embodiment, the resin member may be in direct contact with at least a portion of a lower surface of the one end of the bending portion and in direct contact with at least a portion of a side surface of the lower structure layer.

According to an embodiment, one end of the bending portion may be in direct contact with the upper surface of the pixel circuit layer.

According to an embodiment, the second urethane resin layer may include at least one through hole, and the wiring layer and the pixel circuit layer may be electrically connected to each other through the at least one through hole of the second urethane resin layer.

According to an embodiment, a portion of the second urethane resin layer may be in direct contact with the pixel circuit layer.

According to an embodiment, a portion of the first urethane resin layer may be attached to a lower surface of the organic emission layer.

According to an embodiment, the display apparatus may further include a lower structure layer below the substrate, wherein another end of the bending portion may be attached to a lower surface of the lower structure layer.

### BRIEF DESCRIPTION OF THE DRAWINGS

The above and other aspects, features, and advantages of embodiments of the present disclosure will be more apparent from the following description taken in conjunction with the accompanying drawings.

FIG. 1 is a schematic plan view of a display apparatus according to an embodiment.

FIG. 2 is a schematic equivalent circuit diagram of an embodiment of a pixel of the display apparatus of FIG. 1.

FIG. 3 is a schematic cross-sectional view of an area in an embodiment of the display apparatus of FIG. 1,

FIG. 4 is a schematic cross-sectional view illustrating an area in an embodiment of the display apparatus of FIG. 1.

FIG. 5 is a schematic cross-sectional view illustrating an area in an embodiment of the display apparatus of FIG. 1.

FIG. 6 is a schematic cross-sectional view illustrating another area in an embodiment of the display apparatus of FIG. 1.

FIG. 7 is a cross-sectional view of an area in an embodiment of a bending portion shown in FIG. 6.

FIG. 8 is a schematic cross-sectional view illustrating an example of an area in an embodiment of the display panel of FIG. 6.

FIG. 9 is a schematic cross-sectional view illustrating another example of an area in an embodiment of the display panel of FIG. 6.

FIG. 10 is a schematic cross-sectional view illustrating an example of an area in an embodiment of the display apparatus of FIG. 1.

FIG. 11 is a cross-sectional view of an area of the display apparatus based on a bending portion of FIG. 10.

### DETAILED DESCRIPTION

The following describes in detail some example embodiments, which are illustrated in the accompanying drawings. In this regard, the example embodiments may have different forms and should not be construed as being limited to the descriptions set forth herein. Instead, the embodiments described below and illustrated in the drawings are provided herein merely to explain aspects of the present description. Various modifications may be applied to the example embodiments. Effects and features, and methods for achieving them are clarified with reference to the embodiments described below. However, the embodiments may have different forms and should not be construed as being limited to the descriptions set forth herein.

Hereinafter, the embodiments will now be described in detail with reference to the accompanying drawings. When described with reference to the drawings, identical or corresponding elements may be given the same reference numerals, and redundant description of these elements may be omitted.

In the following embodiments, an element, such as a layer, film, region, or plate, referred to as being “on” another element means that the element may be “directly on” the other element or “indirectly on” the other element with intervening elements therebetween. Also, in the following embodiments, an element, such as a layer, film, region, or plate, referred to as being “below” another element means that the element may be “directly below” the other element or “indirectly below” the other element with intervening elements therebetween.

Sizes of elements in the drawings may be exaggerated or otherwise altered for convenience of explanation or illustration. For example, sizes, thicknesses, and proportions of elements in the drawings may be arbitrarily illustrated for convenience of explanation, and the embodiments disclosed herein are not limited to the illustrated sizes, thicknesses, or proportions. That is, for convenience of description, the size, thickness, and ratio of elements shown in the drawings may be exaggerated and/or simplified for clarity.

Spatially relative terms, such as “below”, “under”, “on”, “above”, “over”, etc., may be terms used herein to easily describe the relationship between elements and features. Such spatially relative terms may describe spaces, directions, etc. as shown in the drawings but may be understood as describing various other directions or various other viewpoints. For example, when a device or element shown in the drawings is turned over, a device or element described as being “below” or “under” the device or element may be interpreted as being positioned in a different direction (e.g., rotated 90 degrees or positioned in opposite directions). Accordingly, the terms “below” or “under” and “on”, “above”, or “over” may include both upward and downward directions. In addition, devices or elements may be oriented differently from those shown in the drawings, and descriptions of spaces or directions described herein may be interpreted in various manners.

In this specification, the order of processes or the order of methods in the description of processing processes, manufacturing methods, etc. may be different from the orders described herein. For example, two processes or two methods described in succession may be performed simultaneously or substantially simultaneously or may be performed in an order opposite to the order described herein.

In the following embodiments, the x-axis, the y-axis, and the z-axis are not limited to three axes of the rectangular coordinate system and may be interpreted in a broader sense. For example, the x-axis, y-axis, and z-axis may be orthogonal to each other or may refer to different directions that are not orthogonal to each other.

As used herein, terms “first”, “second”, “third”, etc. may be used to describe specific elements, and the terms “first”, “second”, “third”, etc. may be used to distinguish one element from another.

An element referred to as being “connected” or “coupled” to another element means that the element may be directly or indirectly connected or coupled to the other element. Similarly, when an element is referred to as being “electrically connected” to another element, the element and the other element may be directly connected electrically or may be indirectly connected electrically via a conductive element therebetween.

An element referred to as being between two elements means that the element is the only element between the two elements or that another element is also between the two elements.

As used herein, the singular forms “a”, “an”, and “the” are intended to include the plural forms as well, unless the context clearly indicates otherwise.

Expressions such as “mix”, “mixture”, “mixing”, “have”, “include”, “comprise”, etc. specify the presence of features, integers, steps, operations, elements, and/or components described herein but do not exclude the presence or addition of one or more features, integers, steps, operations, elements, components, and/or groups.

The term “and/or” includes any and all combinations of one or more of associated listed items. For example, the expression “A and/or B” indicates A, B, or A and B. The expression “at least one” may be used to refer to one or more elements among a plurality of elements. For example, expressions “at least one of a, b, and c” and “at least one selected from the group consisting of a, b, and c” may indicate “a”, “b”, “c”, “a and b”, “b and c”, “a and c”, or “a, b, and c”.

Terms such as “substantially” and “approximately” and other similar terms are used as terms of approximation rather than terms of degree and may be intended to describe inherent variations in measured or calculated values that may be recognized by a person of ordinary skill the art.

In this specification, one layer having the same layer structure as another layer may mean that a plurality of layers included in the one layer may be included in the other layer in the same order. For example, a plurality of layers included in the one layer and a plurality of layers included in the other layer may include the same material and may be formed in the same order.

Electronic or electrical devices and/or any other related devices or components (e.g., some of various modules) according to one or more embodiments described herein may be configured by using any suitable hardware, firmware (e.g., an application-specific integrated circuit (IC)), software, or a combination of firmware and hardware. For example, various components of these devices may be formed on a single IC chip or on separate IC chips. In addition, the various components of these devices may be formed on a flexible printed circuit film, a tape carrier package (TCP), or a printed circuit board (PCB), or on a single substrate. Moreover, the various components of these devices may be processes or threads, run on one or more processors, execute computer program instructions on one or more computing devices, and interact with other system components to perform various functions described herein.

Hereinafter, based on the aforementioned descriptions, a display apparatus according to embodiments is described in detail as follows.

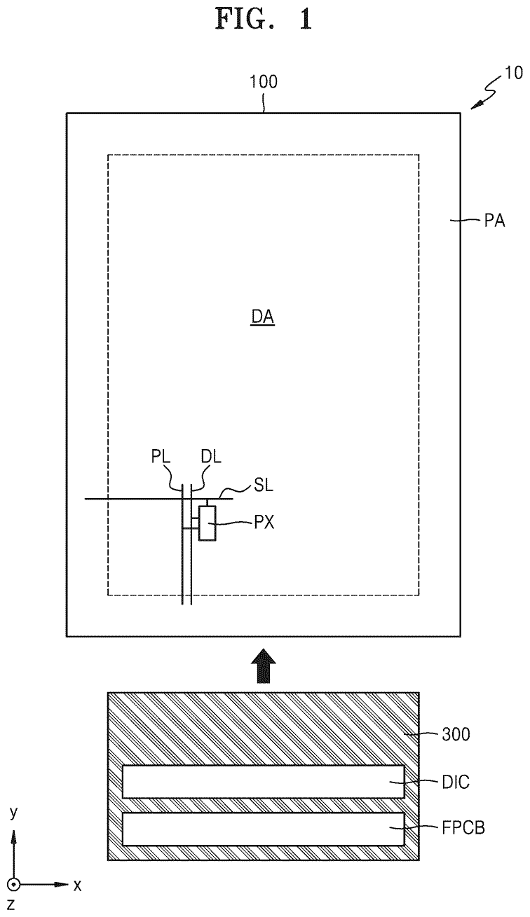

FIG. 1 is a schematic plan view of a display apparatus according to an embodiment.

As shown in FIG. 1, the display apparatus may include a display panel 10. The display apparatus may be any apparatus that includes the display panel 10. For example, the display apparatus may be various apparatuses such as a smartphone, a tablet, a laptop computer, a television, or a billboard. The display apparatus according to an embodiment includes pixels PX, each including thin-film transistors (TFTs) and a capacitor, and the TFTs and the capacitor may be implemented by conductive layers and insulating layers in and on a substrate.

The display panel 10 includes a display area DA and a peripheral area PA located outside the display area DA. Although FIG. 1 illustrates that the display area DA has a rectangular shape, embodiments are not limited thereto. The display area DA may have various other shapes such as a circular shape, an elliptical shape, a polygonal shape, or a specific figure shape.

The display area DA is an area where an image is displayed, and a plurality of pixels PX may be in the display area DA. Each pixel PX may include a display element such as an organic light-emitting device (OLED). Each pixel PX may emit, for example, red, green, or blue light. Each pixel PX may include a pixel circuit including a TFT, a storage capacitor, or the like. The pixel circuit may be connected to a scan line SL configured to transfer a scan signal, a data line DL that crosses the scan line SL and configured to transfer a data signal, and a driving voltage line PL configured to supply a driving voltage. The data line DL and the driving voltage line PL may extend in a y-axis direction (hereinafter, referred to as a first direction), and the scan line SL may extend in an x-axis direction (hereinafter, referred to as a second direction).

Each pixel PX may emit light having a luminance corresponding to an electrical signal from the pixel circuit electrically connected to the pixel PX. The display area DA may display a certain image through the light emitted from the pixels PX. For reference, each pixel PX may be defined as an emission area that emits light of any one color among red, green, and blue.

The peripheral area PA may be an area that does not include pixels and may be an area where an image is not displayed. A power supply line configured to drive the pixels PX may be in the peripheral area PA. Also, a plurality of pads may be in the peripheral area PA, and the aforementioned pads and an IC device such as a driver IC or a PCB including a driving circuit portion may be electrically connected to each other in the peripheral area PA.

For reference, because the display panel 10 includes a substrate 100, the substrate 100 may also include the display area DA and the peripheral area PA. The substrate 100 is described in detail below.

A plurality of transistors may be in the display area DA. According to the type of transistor (N-type or P-type) and/or operating conditions, a first terminal of each of the plurality of transistors may be a source electrode or a drain electrode, and a second terminal thereof may be an electrode different from the first terminal. For example, when the first terminal is a source electrode, the second terminal may be a drain electrode.

The plurality of transistors may include a driving transistor, a data writing transistor, a compensation transistor, an initialization transistor, an emission control transistor, etc. in each pixel circuit. The driving transistor in a pixel circuit may be connected between the driving voltage line PL and the OLED of the associated pixel, and the data writing transistor may be connected to the data line DL and the driving transistor and configured to perform a switching operation of transmitting the data signal transmitted through the data line DL.

The compensation transistor may be turned on in response to the scan signal received through the scan line SL and may connect the driving transistor and the OLED to each other, thereby compensating for a threshold voltage of the driving transistor.

The initialization transistor may be turned on in response to the scan signal received through the scan line SL and may be configured to transmit an initialization voltage to a gate electrode of the driving transistor and initialize the gate electrode of the driving transistor. The scan line SL connected to the initialization transistor may be a separate scan line different from the scan line SL connected to the compensation transistor.

The emission control transistor may be turned on in response to an emission control signal received through an emission control line, and as a result, a driving current may flow through the OLED.

The OLED may include a pixel electrode (anode) and an opposite electrode (cathode) and may receive voltages from the pixel electrode (anode) and the opposite electrode (cathode). The OLED may form part of an image by receiving a driving current from the driving transistor and emitting light having an intensity that depends on the driving current.

A bending portion 300 may be attached to the display panel 10. The bending portion 300 may be attached to the peripheral area PA of the display panel 10. A driving chip DIC and a flexible circuit board FPCB may be on one major surface of the bending portion 300. A portion of the other major surface of the bending portion 300 may be attached to the display panel 10, and the other major surface of the bending portion 300 may refer to a surface opposite to the surface to which the driving chip DIC is attached.

The bending portion 300 may be bent in one direction. For example, one end of the bending portion 300 may be attached to the display panel 10, and the bending portion 300 may be bent such that the other end of the bending portion 300 faces the back of the display panel 10.

The bending portion 300 may include a plurality of layers. The bending portion 300 may include a wiring layer including a conductive material therein, and the driving chip DIC or the flexible circuit board FPCB and the pixel PX or a wire inside the display panel 10 may be electrically connected to each other through the wiring layer. For example, the bending portion 300 may be a chip-on-film. The chip-on-film may electrically connect to one end of the substrate 100 and may contain signal wires configured to supply an electrical signal to the pixels PX in the display area DA. For example, one side of the chip-on-film may couple to the peripheral area PA of the substrate 100. With the signal wires being on the chip-on-film, electrical signals may be supplied through the driving chip DIC.

The bending portion 300 may contain a flexible material (film or tape) that is bendable and thus may be bent in various ways. In order to reduce the volume of the display apparatus, the chip-on-film may have a U-shaped extending from an edge of the substrate 100. The bending of the chip-on-film may place the driving chip DIC and/or the flexible circuit board FPCB on or adjacent to the back of the display panel 10. In a process of manufacturing the display apparatus, a film may firmly attach the driving chip DIC and/or the flexible circuit board FPCB to the back of the display panel 10.

The driving chip DIC may be on the chip-on-film, and the driving chip DIC may include a data driver configured to apply a data voltage to a data line, a gate driver configured to apply a gate-on voltage to a gate line, and a signal controller configured to control operations of the data driver and the gate driver.

The flexible circuit board FPCB may be connected to the other end of the chip-on-film. For example, the flexible circuit board FPCB may be electrically and physically connected to the chip-on-film through an anisotropic conductive film (ACF).

In an embodiment, in order to electrically connect each pixel PX in the display area DA to the driving chip DIC and/or the flexible circuit board FPCB, one side of the bending portion 300 may be attached to the peripheral area PA, and the other side of the bending portion 300 may be attached to the back of the display panel 10.

An organic light-emitting display apparatus is described hereinafter as an example of the display apparatus according to an embodiment, but the display apparatuses according to the present disclosure are not limited thereto. In another embodiment, the display apparatus may include an inorganic light-emitting display apparatus (or inorganic electroluminescence (EL) display apparatus) or a quantum dot light-emitting display apparatus. For example, an emission layer of a display element included in the display apparatus may include an organic material or an inorganic material. Also, the display apparatus may include an emission layer and quantum dots on a path of light emitted from the emission layer.

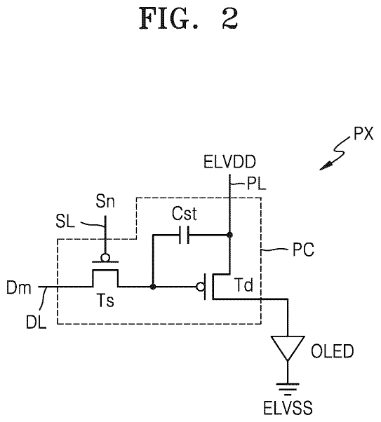

FIG. 2 is a schematic equivalent circuit diagram of an embodiment of the pixel PX in the display apparatus 10 of FIG. 1.

As shown in FIG. 2, each pixel PX may include a pixel circuit PC connected to the scan line SL and the data line DL, and an organic light-emitting device (OLED) connected to the pixel circuit PC.

The pixel circuit PC, in the embodiment shown in FIG. 2, includes a driving thin-film transistor Td, a switching thin-film transistor Ts, and a storage capacitor Cst. The switching thin-film transistor Ts may be connected to the scan line SL and the data line DL that are associated with the pixel PX, and the data line DL may transmit a data signal Dm to the driving thin-film transistor Td in response to a scan signal Sn input through the scan line SL.

The storage capacitor Cst is connected to the switching thin-film transistor Ts and the driving voltage line PL, and the storage capacitor Cst stores a voltage corresponding to a difference between a voltage from the switching thin-film transistor Ts and a first power voltage ELVDD (or driving voltage) on the driving voltage line PL.

The driving thin-film transistor Td may be connected to the driving voltage line PL and the storage capacitor Cst, and in response to the voltage stored in the storage capacitor Cst, the driving thin-film transistor Td may control a driving current flowing from the driving voltage line PL to the OLED. The OLED may emit light having a luminance according to the driving current.

The OLED may receive a second power voltage ELVSS (or common voltage). For example, the OLED may be configured to receive the second power voltage ELVSS (or common voltage) through the electrode (cathode) opposite the electrode (anode) directly connected to the pixel circuit PC, and the OLED may emit light having a certain luminance according to a driving current driven by a voltage difference between the first power voltage ELVDD (or driving voltage) and the second power voltage ELVSS (or common voltage).

Although FIG. 2 illustrates that the pixel circuit PC includes two thin-film transistors and one storage capacitor, embodiments in accordance with this disclosure are not limited thereto. For example, the pixel circuit PC may include two or more storage capacitors and may include three or more TFTs or other types of transistors.

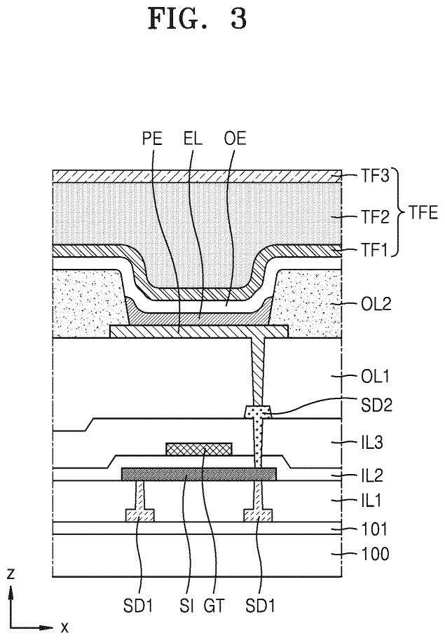

FIG. 3 is a schematic cross-sectional view illustrating an area of an example embodiment of the display apparatus of FIG. 1. The cross-section shown in FIG. 3 is based on the pixel PX in the display area DA.

As described above, the substrate 100 may include areas corresponding to the display area DA and the peripheral area PA, which is outside the display area DA. The substrate 100 may include various flexible or bendable materials. For example, the substrate 100 may include glass, a metal, or polymer resin. Also, the substrate 100 may include polymer resin such as polyethersulfone, polyacrylate, polyetherimide, polyethylene naphthalate (PEN), polyethylene terephthalate (PET), polyphenylene sulfide, polyarylate, polyimide (PI), polycarbonate, or cellulose acetate propionate. Various modifications may be made. For example, the substrate 100 may have a multilayer structure including two layers each including polymer resin, and a barrier layer between the two layers, the barrier layer including an inorganic material (e.g., silicon oxide, silicon nitride, or silicon oxynitride).

A buffer layer 101 may be disposed on the substrate 100. The buffer layer 101 may function as a barrier layer and/or a blocking layer to prevent diffusion of impurity ions, prevent penetration of moisture or external air, and flatten or planarize the surface on which other layers are formed. The buffer layer 101 may include silicon oxide, silicon nitride, or silicon oxynitride. Also, the buffer layer 101 may be configured to adjust the speed of heat transfer during a crystallization process to form a semiconductor layer SI such that the semiconductor layer SI may be evenly crystalized.

A first conductive layer SD1 may be on the buffer layer 101. The first conductive layer SD1 may include at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer SD1 may include a Ti layer, an Al layer, and/or a Cu layer. For example, the first conductive layer SD1 may have a Ti/Al/Ti structure.

A first inorganic insulating layer IL1 may be on the buffer layer 101. The first inorganic insulating layer IL1 may cover the first conductive layer SD1. The first inorganic insulating layer IL1 may include an inorganic material such as silicon oxide, silicon nitride, and/or silicon oxynitride. Also, the first inorganic insulating layer IL1 may substantially cover the entire surface of the substrate 100 and may also have a structure including contact holes. The first inorganic insulating layer IL1 may be formed by using chemical vapor deposition (CVD) or atomic layer deposition (ALD). The embodiments described further below, and modifications thereof may use similar or identical processes to form the first inorganic insulating layer IL1. The first inorganic insulating layer IL1 may include a through hole, and through the through hole, the first conductive layer SD1 may be connected to the semiconductor layer SI to be described below. As a result, the first inorganic insulating layer IL1 may surround side surfaces of a first conductive layer SD1.

The semiconductor layer SI may overlie the first inorganic insulating layer IL1 and the first conductive layer SD1. The semiconductor layer SI may include polysilicon and may include a channel region that is not doped with impurities and include a source region and a drain region that may be formed by doping impurities on opposite sides of the channel region. In this case, the impurities may vary depending on the type of TFT and may include N-type impurities or P-type impurities. Although not shown in the drawings, the display apparatus according to one or more embodiments may further include another semiconductor layer forming transistors on another layer. A second inorganic insulating layer IL2 is a gate insulating layer and may be disposed on the semiconductor layer SI. The second inorganic insulating layer IL2 may provide electrical insulation between the semiconductor layer SI and a gate layer GT. The second inorganic insulating layer IL2 may include an inorganic material, such as silicon oxide, silicon nitride, and/or silicon oxynitride, and may be between the semiconductor layer SI and the gate layer GT. Also, the second inorganic insulating layer IL2 may cover the entire surface of the substrate 100 and may have a structure including contact holes. As described above, an insulating layer IL1 or IL2 including an inorganic material may be formed by using CVD or ALD.

The gate layer GT may be on the second inorganic insulating layer IL2. The gate layer GT may be patterned to vertically overlap the semiconductor layer SI and may include at least one metal from among Mo, Al, Pt, Pd, Ag, Mg, Au, Ni, Nd, Ir, Cr, lithium (Li), Ca, Ti, W, and Cu. The display apparatus according to one or more embodiments may further include another gate layer (not shown) disposed overlying another semiconductor layer for other transistors. In a plan view, the area of the gate layer GT may be less than the area of the semiconductor layer SI.

A third inorganic insulating layer IL3 is an interlayer insulating layer and may be disposed on the gate layer GT. The third inorganic insulating layer IL3 may cover the gate layer GT. The third inorganic insulating layer IL3 may include an inorganic material. For example, the third inorganic insulating layer IL3 may include metal oxide or metal nitride, and in detail, the inorganic material may include silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the third inorganic insulating layer IL3 may have a dual structure of SiOₓ/SiN_{y} or SiNₓ/SiO_{y}.

A second conductive layer SD2 may be disposed on the third inorganic insulating layer IL3. The second conductive layer SD2 may function as an electrode connected to the source/drain region of the semiconductor layer SI through a through hole extending through the third inorganic insulating layer IL3 and the second inorganic insulating layer IL2. The second conductive layer SD2 may include at least one metal selected from among Al, Pt, Pd, Ag, Mg, Au, Ni, Nd, Ir, Cr, Li, Ca, Mo, Ti, W, and Cu. For example, the second conductive layer SD2 may include a Ti layer, an Al layer, and/or a Cu layer. For example, the second conductive layer SD2 may have a Ti/Al/Ti structure.

Although not shown in the drawings, the display apparatus according to one or more embodiments may further include another conductive layer disposed on another insulating layer. For example, the other conductive layer may function as a wiring layer. The other conductive layer may include the same material and have the same layer structure as the first conductive layer SD1 and/or the second conductive layer SD2.

An organic insulating layer OL1 may be disposed on the second conductive layer SD2. The organic insulating layer OL1 covers the upper portion of the second conductive layer SD2 and has a generally flat top surface, and the organic insulating layer OL1 thus may function as a planarization layer. The organic insulating layer OL1 may include an organic material such as acryl, benzocyclobutene (BCB), or hexamethyldisiloxane (HMDSO). Various modifications may be made. The organic insulating layer OL1 may include a single layer or a multilayer structure.

Although not shown in the drawings, the display apparatus according to one or more embodiments may further include another organic insulating layer overlying the first organic insulating layer OL1. The other organic insulating layer may be disposed on the other conductive layer described above and may function as a planarization layer by covering the upper portion of the other conductive layer. The other organic insulating layer and the aforementioned organic insulating layer OL1 may include the same material and have the same layer structure.

A pixel electrode PE may be on the organic insulating layer OL1. Alternatively, the pixel electrode PE may be on the other organic insulating layer described above. However, for convenience of description, the following describes the example in which the pixel electrode PE is disposed on the organic insulating layer OL1.

The pixel electrode PE may be connected to the second conductive layer SD2 through a contact hole formed in the organic insulating layer OL1. A display element may be disposed on the pixel electrode PE. An organic light-emitting material may be used in the display element. That is, the organic light-emitting material may be disposed on, for example, the pixel electrode PE. The pixel electrode PE may include a light-transmissive conductive layer and/or a reflective layer, wherein the light-transmissive conductive layer includes light-transmissive conductive oxide such as indium tin oxide (ITO), indium oxide (In₂O₃), or indium zinc oxide (IZO), and the reflective layer includes a metal such as Al or Ag. For example, the pixel electrode PE may have a three-layer structure of ITO/Ag/ITO.

A pixel-defining layer OL2 may be on the organic insulating layer OL1 and may cover edges of the pixel electrode PE. The pixel-defining layer OL2 may have an opening corresponding to the pixel PX, and the opening may expose at least a central portion of the pixel electrode PE. The pixel-defining layer OL2 may thus define the opening corresponding to the pixel.

The pixel-defining layer OL2 may include an organic material such as PI or HMDSO. Also, a spacer (not shown) may be disposed on the pixel-defining layer OL2. The spacer (not shown) may prevent damage to an OLED due to sagging of a mask during a manufacturing process using the mask. The spacer (not shown) may include an organic insulating material and may include a single layer or a multilayer structure.

An intermediate layer EL and an opposite electrode OE may be in the aforementioned opening. The intermediate layer EL may include a low molecular weight material or a polymer material. When the intermediate layer EL includes a low molecular weight material, the intermediate layer EL may include a hole injection layer, a hole transport layer, an emission layer, an electron transport layer, and/or an electron injection layer. When the intermediate layer EL includes a polymer material, the intermediate layer EL may generally have a structure including a hole transport layer and an emission layer.

The structure of the intermediate layer EL is not limited to the above and may have various structures. For example, at least one of the layers forming the intermediate layer EL may be formed as a single body with the opposite electrode OE. In an embodiment, the intermediate layer EL may include patterned layers including separate areas respectively corresponding to a plurality of pixel electrodes PE.

The opposite electrode OE may include a light-transmissive conductive layer including a light-transmissive conductive oxide such as ITO, In₂O₃, or IZO. The pixel electrode PE may be used as an anode, and the opposite electrode OE may be used as a cathode. The polarity of the electrodes may be reversed.

The opposite electrode OE may be over the display area DA and may be in front of the display area DA. The opposite electrode OE may be formed as a single body that covers a plurality of pixels. The opposite electrode OE may be in electrical contact with a common power supply line (not shown) in the peripheral area PA.

A thin-film encapsulation layer TFE may cover the entire display area DA and may extend to the peripheral area PA to cover at least a portion of the peripheral area PA. The thin-film encapsulation layer TFE may extend to the outside of the common power supply line (not shown).

The thin-film encapsulation layer TFE may include a first inorganic encapsulation layer TF1, a second inorganic encapsulation layer TF3, and an organic encapsulation layer TF2 therebetween. The first inorganic encapsulation layer TF1 and the second inorganic encapsulation layer TF3 may include at least one inorganic material from among aluminum oxide, titanium oxide, tantalum oxide, hafnium oxide, zinc oxide, silicon oxide, silicon oxynitride, and silicon nitride. The first inorganic encapsulation layer TF1 and the second inorganic encapsulation layer TF3 may include a single layer or a multilayer structure including the aforementioned material. The first inorganic encapsulation layer TF1 and the second inorganic encapsulation layer TF3 may include the same material or different materials.

The first inorganic encapsulation layer TF1 and the second inorganic encapsulation layer TF3 may have different thicknesses. A thickness of the first inorganic encapsulation layer TF1 may be greater than a thickness of the second inorganic encapsulation layer TF3. Alternatively, the thickness of the second inorganic encapsulation layer TF3 may be greater than the thickness of the first inorganic encapsulation layer TF1, or the first inorganic encapsulation layer TF1 and the second inorganic encapsulation layer TF3 may have the same thickness.

The organic encapsulation layer TF2 may include a monomer-based material or a polymer-based material. The polymer-based material may include acrylic resin, epoxy-based resin, PI, and/or polyethylene. For example, the organic encapsulation layer TF2 may include acrylate.

According to an embodiment, the thin-film encapsulation layer TFE may be replaced by a cover member that covers the entire display area DA. The cover member may cover at least a portion of the peripheral area PA as well as the display area DA. The cover member may include a rigid member (e.g., glass). In some cases, a transparent filler may be between the cover member and the opposite electrode OE.

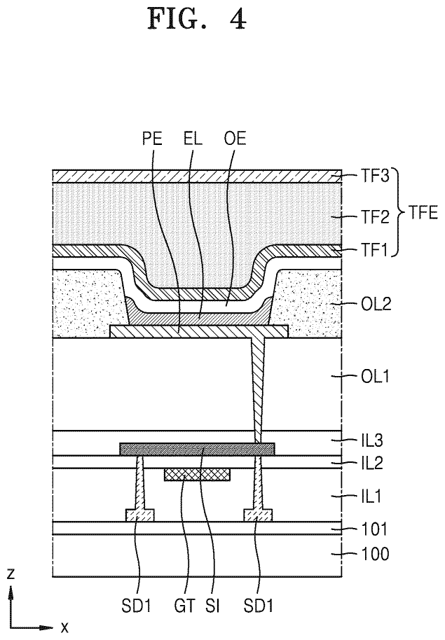

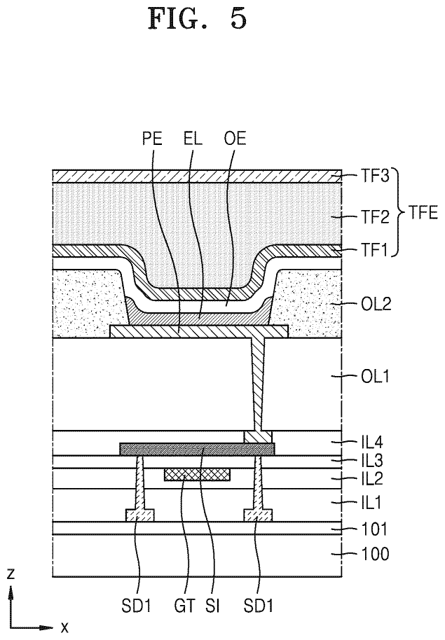

FIG. 4 is a schematic cross-sectional view illustrating an area of another embodiment of the display apparatus of FIG. 1, and FIG. 5 is a schematic cross-sectional view illustrating an area of yet another embodiment of the display apparatus of FIG. 1. For reference, the cross-sections shown in FIGS. 4 and 5 correspond to a pixel PX in the display area DA. For convenience of description, the description of the embodiments shown in FIGS. 4 and 5 focuses mainly on differences from the embodiment shown in FIG. 3.

As shown in FIG. 4, the first conductive layer SD1 may be disposed on the buffer layer 101. The first inorganic insulating layer IL1 may be disposed on the buffer layer 101. The first inorganic insulating layer IL1 may cover the first conductive layer SD1.

The gate layer GT may be disposed on the first inorganic insulating layer IL1. The gate layer GT may be in a trench formed in the first inorganic insulating layer IL1. The second inorganic insulating layer IL2 may be on the first inorganic insulating layer IL1. The second inorganic insulating layer IL2 may also be on the gate layer GT. The second inorganic insulating layer IL2 may cover the upper surface of the gate layer GT.

The semiconductor layer SI may be on the second inorganic insulating layer IL2. The first inorganic insulating layer IL1 and the second inorganic insulating layer IL2 may include common through holes. The first conductive layer SD1 may be connected to the semiconductor layer SI through the through holes in the first inorganic insulating layer IL1 and the second inorganic insulating layer IL2.

The third inorganic insulating layer IL3 may be on the semiconductor layer SI. The third inorganic insulating layer IL3 may cover the semiconductor layer SI. The organic insulating layer OL1 may be on the third inorganic insulating layer IL3.

Unlike in the embodiment of FIG. 3, the second conductive layer SD2 may be omitted in the embodiment shown in FIG. 4, and the pixel electrode PE may be connected to the semiconductor layer SI through a through hole formed in the third inorganic insulating layer IL3 and the organic insulating layer OL1.

As shown in FIG. 5, the first conductive layer SD1 may be on the buffer layer 101. The first inorganic insulating layer IL1 may be on the buffer layer 101 and may cover the first conductive layer SD1.

The second inorganic insulating layer IL2 may be disposed on the first inorganic insulating layer IL1. The gate layer GT may be on the second inorganic insulating layer IL2. The gate layer GT may be in a trench formed in the second inorganic insulating layer IL2. The third inorganic insulating layer IL3 may be on the second inorganic insulating layer IL2. The third inorganic insulating layer IL3 may cover the gate layer GT.

The semiconductor layer SI may be on the third inorganic insulating layer IL3. The first inorganic insulating layer IL1, the second inorganic insulating layer IL2, and the third inorganic insulating layer IL3 may include a common through hole. The first conductive layer SD1 may be connected to the semiconductor layer SI through the through hole commonly formed in the first inorganic insulating layer IL1, the second inorganic layer IL2, and the third inorganic insulating layer IL3.

A fourth inorganic insulating layer IL4 may be on the semiconductor layer SI. The organic insulating layer OL1 may be on the fourth inorganic insulating layer IL4.

Unlike in the embodiment of FIG. 3, the second conductive layer SD2 may be omitted in the embodiment of FIG. 5, and the pixel electrode PE may be connected to the semiconductor layer SI through a through hole formed in the fourth inorganic insulating layer IL4 and the organic insulating layer OL1.

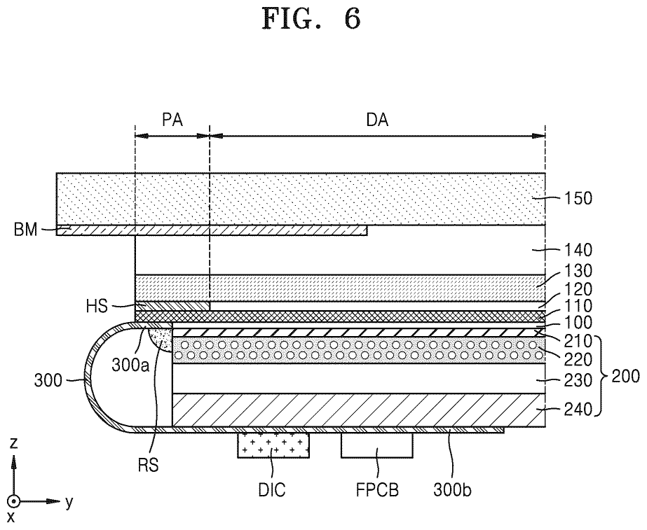

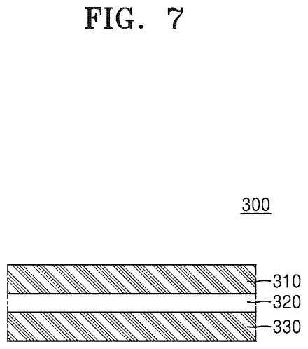

FIG. 6 is a schematic cross-sectional view illustrating an area in an embodiment of the display apparatus of FIG. 1, and FIG. 7 is a cross-sectional view of an area of a bending portion shown in FIG. 6. For reference, unlike FIGS. 3 to 5, the cross-section shown in FIG. 6 is a cross-section of one edge of the display panel 10 and may include a cross-section of the peripheral area PA and a cross-section of an area of the display area DA.

As shown in FIG. 6, the display apparatus according to an embodiment may include the substrate 100, a pixel circuit layer 110 on the substrate 100, and a lower structure layer 200 below the substrate 100.

In an embodiment, the display apparatus may include the substrate 100, the pixel circuit layer 110, and an organic emission layer 120. The substrate 100 has an upper surface and a lower surface. The pixel circuit layer 110 is on the upper surface of the substrate 100, and the organic emission layer 120 is on the pixel circuit layer 110. The display apparatus may further include the bending portion 300 electrically connected to the pixel circuit layer 110.

The pixel circuit layer 110 may be a term used herein for convenience of description. The pixel circuit layer 110 may refer to elements between the substrate 100 and the organic emission layer 120. The pixel circuit layer 110 may be on the substrate 100.

The pixel circuit layer 110 may include, among the elements shown in FIG. 3, the buffer layer 101 on the substrate 100, the semiconductor layer SI, the first inorganic insulating layer IL1, the second inorganic insulating layer IL2, the third inorganic insulating layer IL3, the gate layer GT, the first conductive layer SD1, the second conductive layer SD2, and the organic insulating layer OL1. For example, the pixel circuit layer 110 may refer to elements that are below the pixel electrode PE and over the substrate 100 in FIG. 3.

The pixel circuit layer 110 may include, among the elements shown in FIG. 4, the buffer layer 101 on the substrate 100, the semiconductor layer SI, the first inorganic insulating layer IL1, the second inorganic insulating layer IL2, the third inorganic insulating layer IL3, the gate layer GT, the first conductive layer SD1, and the organic insulating layer OL1. For example, the pixel circuit layer 110 may refer to elements that are below the pixel electrode PE and over the substrate 100 in FIG. 4.

The pixel circuit layer 110 may include, among the elements shown in FIG. 5, the buffer layer 101 on the substrate 100, the semiconductor layer SI, the first inorganic insulating layer IL1, the second inorganic insulating layer IL2, the third inorganic insulating layer IL3, the fourth inorganic insulating layer IL4, the gate layer GT, the first conductive layer SD1, and the organic insulating layer OL1. For example, the pixel circuit layer 110 may refer to elements that are below the pixel electrode PE and over the substrate 100 in FIG. 5.

The organic emission layer 120 may generate light. The organic emission layer 120 may be disposed on the pixel circuit layer 110. For example, the organic emission layer 120 may include the pixel electrode PE, the intermediate layer EL, and the opposite electrode OE. The organic emission layer 120 may be disposed on the pixel circuit layer 110.

A polarizing layer 130 may be on the organic emission layer 120. The polarizing layer 130 may prevent or suppress reflection of external light incident on the display apparatus, thereby improving the display quality of the display apparatus. To this end, the polarizing layer 130 may at least cover the display area DA of the display apparatus.

The polarizing layer 130 may be configured to convert natural light or any polarized light into light linearly polarized in a specific direction and may further include a linear polarized light layer (not shown) for reducing reflection of external light and a phase difference layer (not shown) that shifts the phase of incident light by ¼λ. Accordingly, the phase difference layer (not shown) may change linear polarized light into circular polarized light or change circular polarized light into linear polarized light.

An adhesive layer 140 may be on the polarizing layer 130. The adhesive layer 140 may include a pressure sensitive adhesive (PSA), an optical clear adhesive (OCA), or an optical clear resin (OCR). The adhesive layer 140 may be between a window layer 150 and the polarizing layer 130 and may attach the lower surface of the window layer 150 and the upper surface of the polarizing layer 130 to each other.

The window layer 150 may be on the adhesive layer 140. In a plan view, the window layer 150 may be divided into a transparent area (not shown) and a light-shielding area (not shown). In a plan view, the light-shielding area (not shown) may surround the transparent area (not shown). A light-shielding material layer BM on the lower surface of the window layer 150 may define the light-shielding area (not shown). In a plan view, the light-shielding area (not shown) may refer to an area containing the light-shielding material layer BM. In a plan view, the transparent area (not shown) may refer to an area where the light-shielding material layer BM is absent.

The light-shielding material layer BM may be in a portion of the lower surface of the window layer 150. For example, the light-shielding material layer BM may extend along the edge of the window layer 150. The light-shielding material layer BM may have a specific width from the edge of the window layer 150. The light-shielding material BM may correspond to a bezel of the display apparatus and may need to be wide enough to overlap or hide the bend in the bending portion 300. A display apparatus with a slim bezel may thus require a tight bend in the bending portion 300, but a tight bend creates stress in the bending portion 300 and stress at the electrical connections of the bending portion 300 to the substrate 100. As described further below, the structure of the bending portion 300 in accordance with some embodiments of the present disclosure can withstand tight bends and may be securely attached to provide electrical connections.

The light-shielding material layer BM may be a black matrix and may include various materials capable of absorbing at least a portion of light. For example, the light-shielding material layer BM may include at least one of carbon black, graphite, a chromium-based material, dye, a metal-based reflective film, and a light-absorbing film.

The lower structure layer 200 may be below the substrate 100. The lower structure layer 200 may include a first protective sheet 210 below the substrate 100, and a second protective sheet 220 below the first protective sheet 210. The lower structure layer 200 may further include a digitizer 230 below the second protective sheet 220, and a metal sheet layer 240 below the digitizer 230.

The first protective sheet 210 may include a polymer member. The polymer member of the first protective sheet 210 may have a dark color (e.g., black) to help display the background when the display apparatus is turned off. As an example, the polymer member may act as a cushion that absorbs impact from the outside of the display apparatus and prevents damage to the display panel 10.

The second protective sheet 220 may be a cushion layer. The cushion layer may prevent or significantly reduce damage that external impact could otherwise cause to the display panel 10 and the digitizer 230. For example, the upper surface or the lower surface of the cushion layer may include at least one uneven surface and may absorb external impact through the uneven surface. For example, the cushion layer may have a porous structure including a plurality of air gaps therein. The porous structure of the cushion layer may absorb external impact.

The digitizer 230 may include a pattern layer that is used to detect a signal input from an external electronic pen or the like. In particular, the digitizer 230 may detect the strength, direction, or the like of a signal input from an electronic pen or the like. The digitizer 230 may be electrically connected to a separately provided main circuit board. However, embodiments in accordance with the present disclosure are not limited thereto.

The metal sheet layer 240 may help reinforce the rigidity of the display apparatus and may be used as a noise shield and to disperse heat emitted from surrounding heat-emitting components. As an example, the metal sheet layer 240 may include at least one of steel use stainless (SUS) (e.g., stainless steel (STS)), Cu, Al, or CLAD (e.g., a stacked member in which SUS and Al are alternately arranged). Also, the metal sheet layer 240 may include other alloy materials.

A resin member RS may seal a gap between the bending portion 300 and the lower structure layer 200. The resin member RS may be in direct contact with at least a portion of the lower surface of one end 300a of the bending portion 300 and may be in direct contact with at least a portion of the side surface of the lower structure layer 200. For example, the upper surface of the one end 300a of the bending portion 300 may be attached to the lower surface of the pixel circuit layer 110, and the resin member RS may cover the lower surface of the one end 300a of the bending portion 300.

The resin member RS may be applied along the gap between the bending portion 300 and the lower structure layer 200 and may be cured using ultraviolet light after the resin member RS is applied. For example, the resin member RS may include an OCR. For example, the OCR may include acrylic resin, epoxy-based resin, silicone-based resin, rubber-based resin, etc. These may be used alone or in combination with each other.

An insulating member HS may be on the edge of the substrate 100. The organic emission layer 120 may be on the pixel circuit layer 110. In a plan view, the organic emission layer 120 may be in the display area DA and may not be in the peripheral area PA. Accordingly, in the peripheral area PA, the insulating member HS may be between the pixel circuit layer 110 and the polarizing layer 130, instead of the organic emission layer 120.

The insulating member HS and the organic emission layer 120 may be on the same layer. The insulating member HS may cover an area of the pixel circuit layer 110 corresponding to the peripheral area PA. For example, the insulating member HS may form a flat surface that is level with the surface of the organic emission layer 120, thereby helping other layers on the insulating member HS and the organic emission layer 120 to be stably formed. For example, the insulating member HS may include an inorganic insulating material or an organic insulating material.

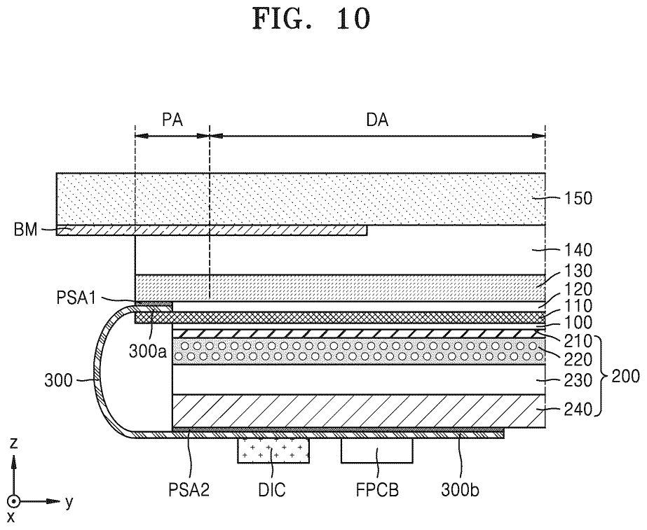

A first adhesive layer PSA1 and a second adhesive layer PSA2 (shown in FIG. 10) may include a PSA, an OCA, or an OCR. The first adhesive layer PSA1 may attach the one end 300a of the bending portion 300 to the polarizing layer 130. The second adhesive layer PSA2 may attach the other end 300b of the bending portion 300 and the lower structure layer 200 below the substrate 100 to each other. The second adhesive layer PSA2 may be between the other end 300b of the bending portion 300 and the lower structure layer 200.

As shown in FIG. 7, the bending portion 300 may include a wiring layer 320, a first urethane resin layer 310, and a second urethane resin layer 330, the wiring layer 320 being electrically connected to the pixel circuit layer 110, the first urethane resin layer 310 covering one surface of the wiring layer 320, and the second urethane resin layer 330 covering the other surface of the wiring layer 320.

The wiring layer 320 may include at least one metal selected from among Al, Pt, Pd, Ag, Mg, Au, Ni, Nd, Ir, Cr, Li, Ca, Mo, Ti, W, and Cu. For example, the wiring layer 320 may include a Ti layer, an Al layer, and/or a Cu layer. For example, the wiring layer 320 may have a Ti/Al/Ti structure.

The first urethane resin layer 310 may cover one surface of the wiring layer 320. For example, the first urethane resin layer 310 may include at least one of a urethane-based monomer and a polyurethane resin.

The second urethane resin layer 330 may cover the other surface of the wiring layer 320. For example, the second urethane resin layer 330 may include at least one of a urethane-based monomer and polyurethane resin.

The wiring layer 320 may be between the first urethane resin layer 310 and the second urethane resin layer 330. For example, the first urethane resin layer 310 may extend parallel to the second urethane resin layer 330. The second urethane resin layer 330 may extend parallel to the first urethane resin layer 310.

Urethane resin has better resistance to bending stress than a polyamide material. For example, urethane resin has a characteristic of being about eight times more elastic than polyamide material. Accordingly, by using the urethane resin in the bending portion 300 (or chip-on-film), the bending portion 300 (or chip-on-film) is less likely to crack during bending and has a more robust structure than a chip-on-film using polyamide material.

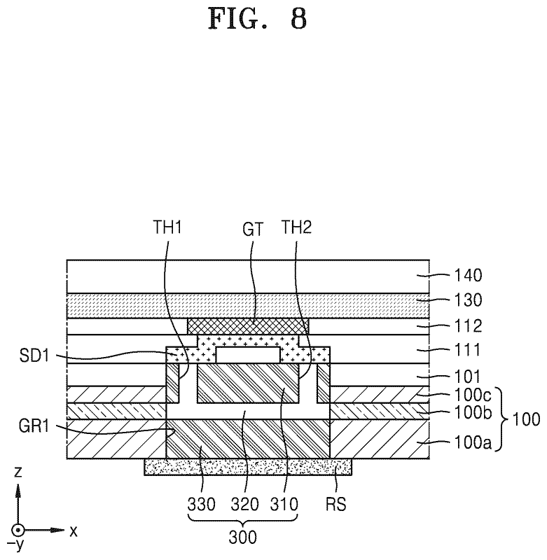

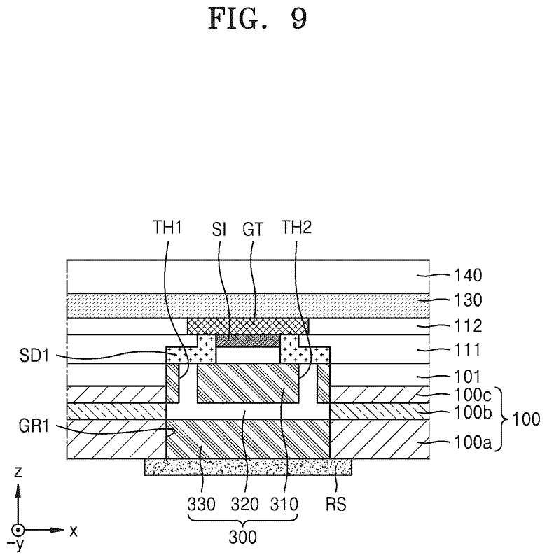

FIG. 8 is a schematic cross-sectional view illustrating an area in an embodiment of the display panel shown in FIG. 6, and FIG. 9 is a schematic cross-sectional view illustrating an area in another embodiment of the display panel shown in FIG. 6. For reference, FIGS. 8 and 9 may show cross-sections taken in a plane that is different from the plane of the cross-section of FIG. 6. For example, FIGS. 8 and 9 show cross-sections taken in a plane that crosses the plane of the cross-section shown in FIG. 6. Also, FIGS. 8 and 9 are cross-sectional views obtained in the peripheral area PA and may be cross-sectional views of an area where the bending portion 300 and the pixel circuit layer 110 are in contact with each other in FIG. 6. The structure shown in FIGS. 3 to 5, which cross-sectional views of the display area DA, may differ from the structure of the cross-sectional view of FIG. 8 and the structure of the cross-sectional view of FIG. 9.

FIG. 8 shows an area where the first conductive layer SD1 and the gate layer GT are in direct contact with each other. In the peripheral area PA, the gate layer GT may be disposed on the first conductive layer SD1.

The substrate 100 may include a first through groove GR1. The first through groove GR1 may be in the peripheral area PA. The first through groove GR1 may be formed on one edge of the substrate 100. The width of the first through groove GR1 and the width of the bending portion 300 may be the same such that the bending portion 300 may be inserted into the first through groove GR1. The one end 300a of the bending portion 300 may be inserted into the first through groove GR1, and as a result, the bending portion 300 and the pixel circuit layer 110 may be electrically connected to each other.

The substrate 100 may have a single-layer structure or a structure in which two or more layers are stacked. For example, the substrate 100 may include a base layer 100a, a barrier layer 100b on the base layer 100a, and a protective layer 100c on the barrier layer 100b.

The base layer 100a may include an insulating material. In an embodiment, the base layer 100a may include PI, but the material of the base layer 100a is not limited thereto.

The barrier layer 100b may be disposed on the base layer 100a. The barrier layer 100b may prevent the penetration of impurity elements into or from the substrate 100. In an embodiment, the barrier layer 100b may include one or more material selected from the group consisting of SiOₓ and SiNₓ, but the material of the barrier layer 100b is not limited thereto. The barrier layer 100b may have a single-layer structure or a structure in which two or more layers are stacked. In an embodiment in which the barrier layer 100b includes two layers, the two layers may include different materials. For example, a first layer may include SiOₓ, and a second layer may include SiNₓ. However, this is merely an example, and the structure of the barrier layer 100b is not limited thereto. Also, in another embodiment, the barrier layer 100b may be omitted according to the material or process conditions of the substrate 100.

The protective layer 100c may be disposed on the barrier layer 100b. The protective layer 100c may include an organic material or an inorganic material. For example, the protective layer 100c may include one or more material selected from among PI, PET, and PEN, but this is merely an example. The material of the protective layer 100c is not limited thereto.

In order to electrically connect the bending portion 300 and the pixel circuit layer 110 to each other, the first urethane resin layer 310 of the bending portion 300 may include at least one through hole. The wiring layer 320 of the bending portion 300 and the pixel circuit layer 110 may be electrically connected to each other through the at least one through hole. For example, the wiring layer 320 of the bending portion 300 may extend through the at least one through hole included in the first urethane resin layer 310, so that the wiring layer 320 of the bending portion 300 and the first conductive layer SD1 of the pixel circuit layer 110 may be in direct contact with each other or electrically connected to each other. Also, the first urethane resin layer 310 may be in direct contact with the pixel circuit layer 110, and the first urethane resin layer 310 and the first conductive layer SD1 may be in direct contact with each other according to the shape of the first conductive layer SD1 of the pixel circuit layer 110. The wiring layer 320 may be in direct contact with the first conductive layer SD1. For example, in the peripheral area PA, the pixel circuit layer 110 may include the first conductive layer SD1 on the first urethane resin layer 310, and the gate layer GT disposed on the first conductive layer SD1 and electrically connected to the wiring layer 320 in the peripheral area PA.

The first urethane resin layer 310 according to an embodiment may include a first through hole TH1 and a second through hole TH2. Although only the first through hole TH1 and the second through hole TH2 are shown in FIG. 8 for convenience of description, the first urethane resin layer 310 may further include more through holes.

As shown in FIG. 8, a first insulating material layer 111 may be disposed on the buffer layer 101. The first insulating material layer 111 may cover the first conductive layer SD1. The gate layer GT may be disposed on the first insulating material layer 111. A second insulating material layer 112 may be disposed on the first insulating material layer 111. The second insulating material layer 112 may cover side surfaces of the gate layer GT.

In an embodiment, the first insulating material layer 111 may include a plurality of layers that are simultaneously formed with or include the same material as the first inorganic insulating layer IL1 and the second inorganic insulating layer IL2 in FIG. 3. The second insulating material layer 112 may be simultaneously formed with or include the same material as the third inorganic insulating layer IL3 in FIG. 3.

In an embodiment, the first insulating material layer 111 and the second insulating material layer 112 may be simultaneously formed with or include the same material as the first inorganic insulating layer IL1 in FIG. 4.

In an embodiment, the first insulating material layer 111 may be simultaneously formed with or include the same material as the first inorganic insulating layer IL1 in FIG. 5. The second insulating material layer 112 may be simultaneously formed with or include the same material as the second inorganic insulating layer IL2 in FIG. 5.

FIG. 9 shows a display apparatus according to an embodiment that further includes the semiconductor layer SI that is simultaneously in contact with the first conductive layer SD1 and the lower surface of the gate layer GT in the peripheral area PA. The semiconductor layer SI may be between a portion of the first conductive layer SD1 connected to the wiring layer 320 through the first through hole TH1 and another portion of the first conductive layer SD1 connected to the wiring layer 320 through the second through hole TH2, and the semiconductor layer SI may electrically connect the portions of the first conductive layer SD1 to each other.

As shown in FIG. 9, the first insulating material layer 111 may be disposed on the buffer layer 101. The first insulating material layer 111 may cover the first conductive layer SD1. The gate layer GT may be disposed on the first insulating material layer 111. The second insulating material layer 112 may be disposed on the first insulating material layer 111. The second insulating material layer 112 may cover the side surfaces of the gate layer GT. A portion of the first insulating material layer 111 may be between the semiconductor layer SI and the first urethane resin layer 310.

In an embodiment, the first insulating material layer 111 may include a plurality of layers that are simultaneously formed with or include the same material as the first inorganic insulating layer IL1 and the second inorganic insulating layer IL2 in FIG. 3. The second insulating material layer 112 may be simultaneously formed with or include the same material as the third inorganic insulating layer IL3 in FIG. 3.

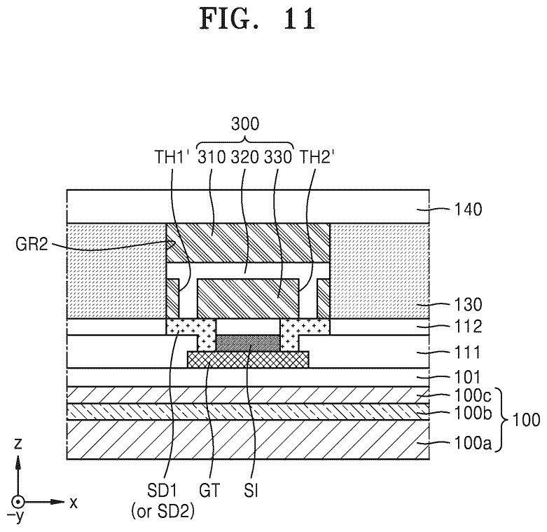

FIG. 10 is a schematic cross-sectional view illustrating an area in an embodiment of the display apparatus of FIG. 1, and FIG. 11 is a cross-sectional view of an area of the display apparatus based on a bending portion of FIG. 10. For reference, descriptions of elements in FIGS. 10 and 11 that are substantially the same as those described above may be omitted.

As shown in FIG. 10, the one end 300a of the bending portion 300 may be disposed on the upper surface of the pixel circuit layer 110. The bending portion 300 may be electrically connected to a pixel through the upper surface of the pixel circuit layer 110. For a stable structure, the lower surface of the one end 300a of the bending portion 300 may face the pixel circuit layer 110, the upper surface of the one end 300a of the bending portion 300 may face the polarizing layer 130, and a first adhesive layer PSA1 may be between the one end 300a of the bending portion 300 and the lower surface of the polarizing layer 130.

The one end 300a of the bending portion 300 and the polarizing layer 130 may be fixed to each other through the first adhesive layer PSA1. The first adhesive layer PSA1 may include a PSA, an OCA, or an OCR. The first adhesive layer PSA1 may attach the one end 300a of the bending portion 300 and the polarizing layer 130 to each other. The first adhesive layer PSA1 may be between the one end 300a of the bending portion 300 and the polarizing layer 130.

As shown in FIG. 11, the polarizing layer 130 may include a second through groove GR2. The second through groove GR2 may be in the peripheral area PA. The second through groove GR2 may be formed on one edge of the polarizing layer 130. The width of the second through groove GR2 and the width of the bending portion 300 may be the same such that the one end 300a of the bending portion 300 may be inserted into the second through groove GR2. The one end 300a of the bending portion 300 may be inserted into the second through groove GR2, and as a result, the bending portion 300 and the pixel circuit layer 110 may be electrically connected to each other.

In order to electrically connect the bending portion 300 and the pixel circuit layer 110 to each other, the second urethane resin layer 330 of the bending portion 300 may include at least one through hole. The wiring layer 320 of the bending portion 300 and the pixel circuit layer 110 may be electrically connected to each other through the at least one through hole. For example, the wiring layer 320 may extend through the at least one through hole included in the second urethane resin layer 330, and the wiring layer 320 of the bending portion 300 and the first conductive layer SD1 (or the second conductive layer SD2) of the pixel circuit layer 110 may be in direct contact with each other or electrically connected to each other. Also, the second urethane resin layer 330 may be in direct contact with the pixel circuit layer 110, and the second urethane resin layer 330 and the first conductive layer SD1 may be in direct contact with each other according to the shape of the first conductive layer SD1 of the pixel circuit layer 110 in the peripheral area PA. The wiring layer 320 may be in direct contact with the first conductive layer SD1 (or the second conductive layer SD2). FIG. 11 and the following description focuses on an example in which the first conductive layer SD1 contacts the wiring layer 320 in the peripheral area PA, but the pixel circuit layer 110 may include a different conductive layer (such as the second conductive layer SD2) that is patterned to directly contact the wiring layer 320 in the peripheral area PA.

For example, the second urethane resin layer 330 may include a third through hole and a fourth through hole. Although only the third through hole and the fourth through hole are shown in FIG. 11 for convenience of description, the second urethane resin layer 330 may further include more through holes.

The peripheral area PA of the pixel circuit layer 110 in accordance with an example embodiment may include the gate layer GT on the substrate 100 and the first conductive layer SD1 on the gate layer GT. The display apparatus according to an embodiment may further include the semiconductor layer SI that is simultaneously in contact with the upper surface of the gate layer GT and the first conductive layer SD1 in the peripheral area PA. The semiconductor layer SI may be between a portion of the first conductive layer SD1 connected to the wiring layer 320 through the third through hole and another portion of the first conductive layer SD1 connected to the wiring layer 320 through the fourth through hole, and the semiconductor layer SI may electrically connect the portions of the first conductive layer SD1 to each other.

The polarizing layer 130 may be on the first urethane resin layer 310, and due to the adhesion between the polarizing layer 130 and the first urethane resin layer 310, a sealing effect similar to the resin member RS of FIG. 6 described above may be implemented.

As shown in FIG. 11, the first insulating material layer 111 may be on the buffer layer 101. The first insulating material layer 111 may cover the gate layer GT. The first conductive layer SD1 may be on the first insulating material layer 111. The second insulating material layer 112 may be on the first insulating material layer 111. The second insulating material layer 112 may cover side surfaces of the first conductive layer SD1. A portion of the second insulating material layer 112 may be between the semiconductor layer SI and the second urethane resin layer 330.

In an embodiment, the first insulating material layer 111 may be simultaneously formed with or include the same material as the second inorganic insulating layer IL2 in FIG. 5. The first inorganic insulating layer IL1 of FIG. 5 may be omitted from FIG. 11 for convenience of description. The second insulating material layer 112 may be simultaneously formed with or include the same material as the third inorganic insulating layer IL3 in FIG. 5.

As described above, the effects of the display apparatus according to the one or more embodiments may be as follows.

First, by using a bending portion (chip-on-film) that utilizes urethane resin instead of a polyamide material, a display apparatus that is robust against bending stress may be provided.

Second, by using a resin member as shown in FIG. 6, the bending portion is firmly attached, and thus, a display apparatus that is more robust against bending stress than a conventional display apparatus may be provided.

Third, as shown in FIGS. 8 and 9, one end of the bending portion may be inserted through a first through groove formed in a substrate, and thus, electrical connection between a driving chip and a pixel may be easily and stably implemented.

Fourth, as shown in FIG. 10, because the position at which the one end of the bending portion is attached may be changed, various structural changes may be made according to the characteristics of the display apparatus, and a display apparatus that is more robust against bending stress than the conventional display apparatus may be provided.

Fifth, as shown in FIG. 11, the one end of the bending portion may be inserted through a second through groove formed in a polarizing layer, and accordingly, electrical connection between the driving chip and the pixel may be easily and stably implemented.

While certain embodiments have been described, it will be readily apparent to those of ordinary skill in the art that various modifications may be made without departing from the spirit and scope of the disclosure. Unless otherwise stated, the description of features or aspects within the embodiments should generally be considered to be applicable to other similar features or aspects of other embodiments. Accordingly, as it is apparent to those of ordinary skill in the art, features or components described in association with specific embodiments may be combined with features or components described in association with other embodiments. Therefore, the foregoing should not be construed as being limited to the specific embodiments set forth herein but should be understood to be intended to be combined with or applied to other embodiments. Therefore, the true technical scope of protection of the disclosure should be defined by the technical spirit of the appended claims.

According to the one or more embodiments described above, a display panel having a slim bezel may be achieved. However, the scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including an upper surface and a lower surface;
a pixel circuit layer on the upper surface of the substrate;
an emission layer on the pixel circuit layer; and
a bending portion including a wiring layer, a first urethane resin layer, and a second urethane resin layer, the wiring layer being electrically connected to the pixel circuit layer, the first urethane resin layer covering one surface of the wiring layer, and the second urethane resin layer covering another surface of the wiring layer.

2. The display apparatus of claim 1, wherein one end of the bending portion is in a groove formed on one edge of the substrate.

3. The display apparatus of claim 2, wherein the first urethane resin layer includes at least one through hole, and
the wiring layer and the pixel circuit layer are electrically connected to each other through the at least one through hole of the first urethane resin layer.

4. The display apparatus of claim 3, wherein the first urethane resin layer is in direct contact with the pixel circuit layer.

5. The display apparatus of claim 2, wherein the substrate includes a display area and a peripheral area, the peripheral area being around the display area.

6. The display apparatus of claim 5, wherein the groove is in the peripheral area.

7. The display apparatus of claim 5, wherein, in the peripheral area, the pixel circuit layer includes:
a conductive layer on the first urethane resin layer; and
a gate layer on the conductive layer, the gate layer being electrically connected to the conductive layer in the peripheral area.

8. The display apparatus of claim 7, wherein the wiring layer is in direct contact with the conductive layer.

9. The display apparatus of claim 7, further comprising a semiconductor layer simultaneously in contact with a lower surface of the gate layer and the conductive layer.

10. The display apparatus of claim 2, further comprising a lower structure layer below the substrate.

11. The display apparatus of claim 10, wherein a second end of the bending portion is attached to a lower surface of the lower structure layer.

12. The display apparatus of claim 11, further comprising a driving chip arranged around the second end of the bending portion on the first urethane resin layer.

13. The display apparatus of claim 10, further comprising a resin member that seals a gap between the bending portion and the lower structure layer.

14. The display apparatus of claim 13, wherein the resin member is in direct contact with at least a portion of a lower surface of the one end of the bending portion and in direct contact with at least a portion of a side surface of the lower structure layer.

15. The display apparatus of claim 1, wherein one end of the bending portion is in direct contact with the upper surface of the pixel circuit layer.

16. The display apparatus of claim 15, wherein the second urethane resin layer includes at least one through hole, and
the wiring layer and the pixel circuit layer are electrically connected to each other through the at least one through hole of the second urethane resin layer.

17. The display apparatus of claim 16, wherein a portion of the second urethane resin layer is in direct contact with the pixel circuit layer.

18. The display apparatus of claim 16, wherein a portion of the first urethane resin layer is attached to a lower surface of the emission layer.

19. The display apparatus of claim 16, further comprising a lower structure layer below the substrate,
wherein a second end of the bending portion is attached to a lower surface of the lower structure layer.
